(19) United States
(12) Patent Application Publication
(10) Pub. No.: US 2007/0096180 A1
(43) Pub. Date: May 3, 2007

(54) Semiconductor device and method for manufacturing the same

(76) Inventors: Koji Yamakawa, Tokyo (JP); Soichi Yamazaki, Yokohama-shi (JP); Osamu Hidaka, Hachioji-shi (JP); Osamu Arisumi, Kuwana-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/524,267

(22) Filed: Sep. 21, 2006

(30) Foreign Application Priority Data
Sep. 21, 2005 (JP) 2005-273856

(51) Int. Cl. H01L 29/94; H01L 29/76; H01L 31/00

(52) U.S. Cl. 257/295

(57) ABSTRACT

A semiconductor device includes a semiconductor substrate, and a ferroelectric capacitor provided on the semiconductor substrate, the ferroelectric capacitor comprising a lower electrode, a first ferroelectric film provided on the lower electrode including Pb(ZrₓTi₁₋ₓ)O₃ and having a tetragonal crystal system whose crystal direction is oriented in a <111> direction, a second ferroelectric film provided on the first ferroelectric film including Pb(Zr_{y}Ti_{1-y})O₃ and having a tetragonal crystal system whose crystal direction is oriented in the <111> direction, and an upper electrode provided on the second ferroelectric film.

### CROSS-REFERENCE TO RELATED APPLICATIONS

This application is based upon and claims the benefit of priority from prior Japanese Patent Application No. 2005-273856, filed Sep. 21, 2005, the entire contents of which are incorporated herein by reference.

### BACKGROUND OF THE INVENTION

1. Field of the Invention

The present invention relates to a semiconductor device comprising a ferroelectric capacitor and a method for manufacturing the same.

2. Description of Related Art

In recent years, ferroelectric random access memories (FeRAM: ferroelectric random access memory) have been developed from the standpoint of advantages such as low power consumption, possibility for miniaturization, improvement in speed, increase of endurance, non volatility, and possibility for random access.

One of ferroelectric films is a film (PZT film) forming of PZT (Pb(ZrₓTi₁₋ₓO₃) as a main material. A PZT film has an amount of residual polarization and an anti-field which are required for a ferroelectric random access memory. Therefore, a ferroelectric random access memory using such a PZT film has been proposed (Jpn. Pat. Appln. KOKAI Publication No. 2003-142659).

A noble metal film, a noble metal oxide film, or a conductive oxide film such as a Pt film, an Ir film, an IrO₂ film, an Ru film or an RuO₂ film is used as a lower electrode of the ferroelectric capacitor. A noble metal film or noble metal oxide film such as a Pt film, an Ir film, an IrO₂ film, an Ru₂ film, an RuO₂ film, an SrRuO₃ film, an LaNiO₃ film, an (La, Sr) CoO₃ film, or a conductive composite oxide film which is typified by a perovskite structure is used as an upper electrode.

A process for forming a PZT film is consistent with a process for a semiconductor memory. For this reason, a PZT film is formed by using sputtering process, MOCVD process, sol-gel process, or the like.

The characteristic of the PZT film is greatly affected by its own composition (a Ti/Zr ratio, a doping material, or the like). A change in the characteristic of the PZT film has a great effect on the characteristic of the ferroelectric capacitor. A change in the characteristic of the ferroelectric capacitor has a great effect on the characteristic of the ferroelectric memory (memory characteristic). For this reason, it is difficult for a PZT ferroelectric capacitor of a conventional structure to form a ferroelectric memory having memory performance as designed including reliability.

### BRIEF SUMMARY OF THE INVENTION

According to another aspect of the present invention, there is provided a semiconductor device comprising: a semiconductor substrate; and a ferroelectric capacitor provided on the semiconductor substrate, the ferroelectric capacitor comprising a lower electrode; a first ferroelectric film provided on the lower electrode including Pb(ZrₓTi₁₋ₓ)O₃ and having a tetragonal crystal system whose crystal direction is oriented in a <111> direction; a second ferroelectric film provided on the first ferroelectric film including Pb(Zr_{y}Ti_{1-y})O₃ and having a tetragonal crystal system whose crystal direction is oriented in the <111> direction; and an upper electrode provided on the second ferroelectric film.

According to an aspect of the present invention, there is provided a method for manufacturing a semiconductor device comprising a semiconductor substrate and a ferroelectric capacitor provided on the semiconductor substrate, the method comprising: forming the ferroelectric capacitor; forming a multilayered lower electrode, the multilayered lower electrode including a first conductive film having a (111) plane; and a second conductive film provided on the first conductive film including SrRuO₃ and being thinner than the first conductive film; forming a ferroelectric film on the lower electrode, the ferroelectric film including a first ferroelectric film including Pb(ZrₓTi₁₋ₓ)O₃ and having a tetragonal crystal system whose crystal direction is oriented in a <111> direction; and a second ferroelectric film provided on the first ferroelectric film including Pb(Zr_{y}Ti_{1-y})O₃ and having a tetragonal crystal system whose crystal direction is oriented in the <111> direction; and forming an upper electrode on the ferroelectric film.

### BRIEF DESCRIPTION OF THE SEVERAL VIEWS OF THE DRAWING

FIG. 1 is a cross-sectional view showing a manufacturing process for a ferroelectric memory of a first embodiment;

FIG. 2.is a cross-sectional view showing a manufacturing process for the ferroelectric memory of the first embodiment following FIG. 1;

FIG. 3 is a cross-sectional view showing a manufacturing process for the ferroelectric memory of the first embodiment following FIG. 2;

FIG. 4 is a cross-sectional view showing a manufacturing process for the ferroelectric memory of the first embodiment following FIG. 3;

FIG. 5 is a cross-sectional view showing a manufacturing process for the ferroelectric memory of the first embodiment following FIG. 4;

FIG. 6 is a cross-sectional view showing a manufacturing process for the ferroelectric memory of the first embodiment following FIG. 5;

FIG. 7 is a cross-sectional view showing a manufacturing process for the ferroelectric memory of the first embodiment following FIG. 6;

FIG. 8 is a cross-sectional view showing a manufacturing process for the ferroelectric memory of the first embodiment following FIG. 7;

FIG. 9 is a cross-sectional view showing a manufacturing process for the ferroelectric memory of the first embodiment following FIG. 8;

FIG. 10 is a cross-sectional view showing a manufacturing process for the ferroelectric memory of the first embodiment following FIG. 9;

FIG. 11 is a cross-sectional view showing a manufacturing process for the ferroelectric memory of the first embodiment following FIG. 10;

FIG. 12 is a cross-sectional view showing a manufacturing process for a ferroelectric memory of a second embodiment;

FIG. 13 is a cross-sectional view showing a manufacturing process for the ferroelectric memory of the second embodiment following FIG. 12;

FIG. 14 is a cross-sectional view showing a manufacturing process for the ferroelectric memory of the second embodiment following FIG. 13;

FIG. 15 is a cross-sectional view showing a manufacturing process for the ferroelectric memory of the second embodiment following FIG. 14;

FIG. 16 is a cross-sectional view showing a manufacturing process for the ferroelectric memory of the second embodiment following FIG. 15;

FIG. 17 is a cross-sectional view showing a manufacturing process for the ferroelectric memory of the second embodiment following FIG. 16;

FIG. 18 is a cross-sectional view showing a manufacturing process for the ferroelectric memory of the second embodiment following FIG. 17;

FIG. 19 is a cross-sectional view showing a manufacturing process for the ferroelectric memory of the second embodiment following FIG. 18;

FIG. 20 is a cross-sectional view showing a manufacturing process for the ferroelectric memory of the second embodiment following FIG. 19;

FIG. 21 is a graph showing a relationship between percentage (film thickness ratio) of a thickness of first PZT crystalline film to a sum of the film thickness of the first PZT crystalline film and a film thickness of a second PZT crystalline film and amount of switching electric charge;

FIG. 22 is a graph showing a relationship between a ratio of a thickness of a first PZT crystalline film to a sum of the film thickness of the first PZT crystalline film and a film thickness of a second PZT crystalline film and coercive voltage;

FIG. 23 is a graph showing a relationship between a ratio of a thickness of a first PZT crystalline film to a sum of the film thickness of the first PZT crystalline film and a film thickness of a second PZT crystalline film and amount of hysteresis shift;

FIG. 24 is a graph showing a relationship between a ratio of a thickness of a first PZT crystalline film to a sum of the film thickness of the first PZT crystalline film and a film thickness of a second PZT crystalline film and a ratio of amount of polarization; and

FIGS. 25A and 25B are cross-sectional views for explanation of modified examples of the embodiments.

### DETAILED DESCRIPTION OF THE INVENTION

Hereinafter, embodiments of the present invention will be described with reference to the drawings.

### FIRST EMBODIMENT

FIGS. 1 to 11 are cross-sectional views showing process for manufacturing a ferroelectric memory of a first embodiment of the present invention.

[FIG. 1]

First, MOS transistors are formed on a silicon substrate 1 by well-known process, and then a CMOS structure is formed. For ease of explanation, only one MOS transistor is shown in FIG. 1.

In FIG. 1, reference numeral 2 denotes source/drain regions, 3 denotes a gate insulating film, 4 denotes a gate electrode, 5 denotes a gate upper insulating film (for example, a silicon nitride film), and 6 denotes a spacer (for example, a silicon nitride film).

An SiO₂ system insulating film 7 such as a PSG film or a BPSG film is deposited on a region including the CMOS structure (transistor region) by CVD process, thereafter, the surface of the SiO₂ system insulating film 7 is planarized by chemical mechanical polishing (CMP) process. A laminated insulating film 8 including a silicon oxide film and a silicon nitride film is deposited on the SiO₂ system insulating film 7 by CVD process. Hereinafter, the SiO₂ system insulating film 7 and the laminated insulating film 8 are collectively referred as an interlayer insulating film 9.

[FIG. 2]

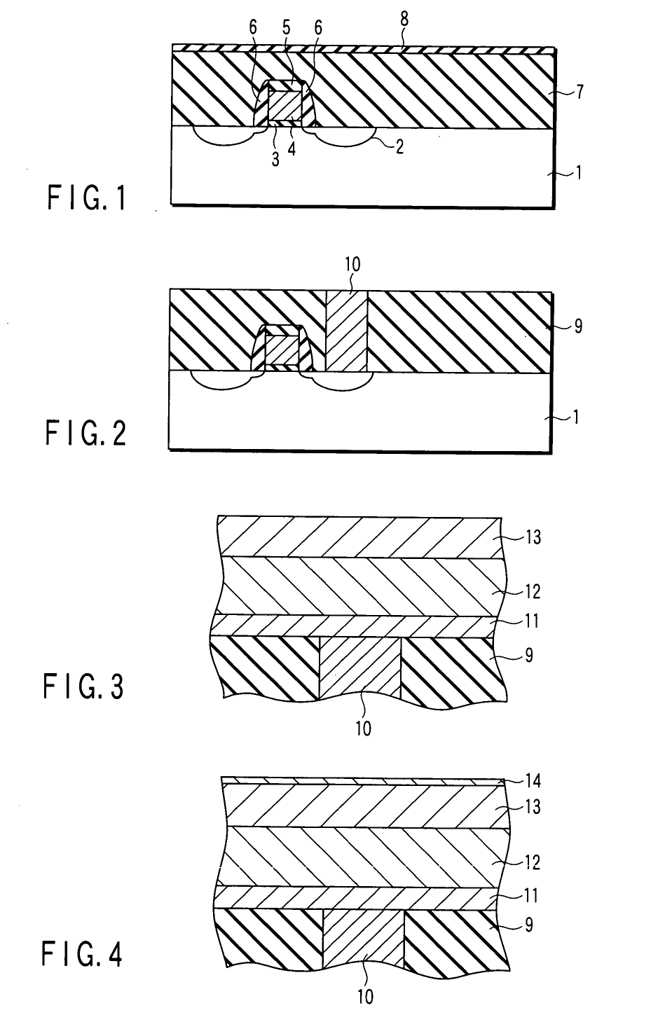

A connection hole reaching the source/drain regions 2 is formed in the interlayer insulating film 9 by etching the interlayer insulating film 9, thereafter, a plug 10 is formed in the connection hole by blanket CVD process and CMP process. A material for the plug 10 is, for example, tungsten (W) or polycrystalline silicon. Here, suppose that the material for the plug 10 is polycrystalline silicon.

[FIG. 3]

A barrier film 11 is formed on a region including the plug 10. The barrier film 11 is formed by, for example, DC magnetron sputtering process.

The barrier film 11 suppresses the surface of the plug 10 from being oxidized in a process for forming a PZT film, or during anneal in oxygen for ensuring the capacitor characteristic, which will be carried out later.

Here, a TiAlN film is used as the barrier film 11. A thickness of the TiAlN film is 50 nm. A Ti/Al mole ratio of the TiAlN film is 0.7/0.3. A TiN film may be used as the barrier film 11.

In FIG. 3, the barrier film 11 is formed on the entire undersurface of a first lower electrode 12. However, it is not necessarily that case. For example, the plug 10 is recessed, and the barrier film 11 may be formed only on the plug 10.

The first lower electrode 12 is formed on the barrier film 11.

Here, an Ir film is used as the first lower electrode 12. A thickness and a crystalline plane of the Ir film are 100 nm and (111), respectively. The Ir film is formed by sputtering process. The first lower electrode 12 (Ir film), along with the barrier film 11, suppresses the surface of the plug 10 from being oxidized by anneal in an atmosphere including oxygen, or the like.

A second lower electrode 13 is formed on the first lower electrode 12.

Here, the second lower electrode 13 is an IrO₂ film. A thickness of the IrO₂ film is 50 nm. The IrO₂ film is formed by DC magnetron sputtering process innovating oxygen. The conditions for the DC magnetron sputtering process innovating oxygen are, for example, Ar/O₂ flow ratio=30/70, deposition temperature=room temperature (RT), sputtering power=1 kW, and sputtering target diameter=300 mm.

When a PZT crystalline film is directly formed on the Ir layer, Pb contained in the PZT crystalline film diffuses into the Ir layer, and reacts with Ir to deteriorate the characteristic of the PZT crystalline film. In the present embodiment, however, the characteristic of the PZT crystalline film which is to be formed in a subsequent process is suppressed from deteriorating because the second lower electrode 13 (IrO₂ film) is formed on the first lower electrode 12 (Ir layer).

The first and second lower electrodes 12 and 13 immediately after being formed were examined by X-ray diffraction. As a result, an IrO₂ film (the second lower electrode 13) having a state close to amorphous state was detected. When observing the morphology of the IrO₂ film, this had a planar structure in which no grains were seen.

Here, after the IrO₂ film is formed and before the PZT film (capacitor ferroelectric film) is formed, the crystalline characteristic of the IrO₂ film may be improved by thermal treatment. The thermal treatment is, for example, RTO (rapid thermal oxidation). Temperature for the thermal treatment is, for example, 550° C. When the thermal treatment was applied, a composition having grown up in a columnar form was observed. It has been verified that the IrO₂ film is crystallized by X-ray diffraction.

The IrO₂ film may be formed by high temperature sputtering process at about 200 to 400° C. In this case, a crystallized IrO₂ film (IrO₂ crystalline film) is formed in the high temperature sputtering process. The IrO₂ crystalline film is formed in the same manner when RTO for crystallizing the amorphous IrO₂ film is carried out after an IrO₂ film is formed on an amorphous IrO₂ film to be the second lower electrode 13.

[FIG. 4]

A Pt thin film 14 (buffer layer) is formed on the second lower electrode 13. The Pt thin film 14 is formed by DC magnetron sputtering process at a temperature of about 200 to 400° C. A thickness of the Pt thin film 14 is about 10 to 50 nm.

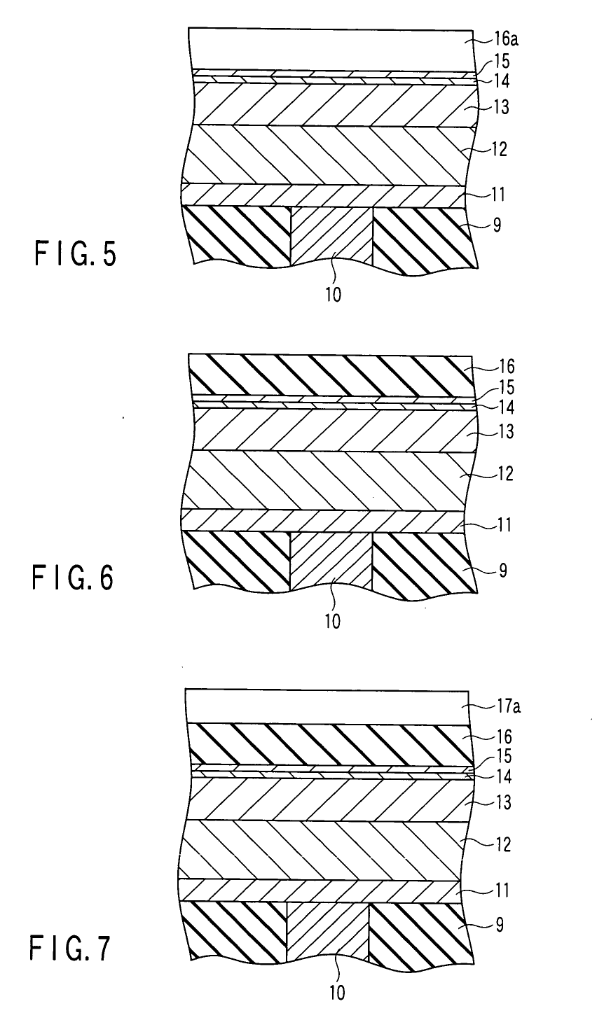

When there is only an Ir film as a film serving as an oxygen barrier film, the Pt thin film 14 is not formed in some cases. This is because there is possibility that deterioration of shape of the Pt thin film 14 is occurred by silicide reaction between Pt and Si diffused from the plug 10 (Si).

[FIG. 5]

A third lower electrode 15 is formed on the Pt thin film 14.

Here, the third lower electrode 15 is a thin film (SRO film) made of SrRuO₃ as a main material.

The SRO film is formed by DC magnetron sputtering process using a conductive SRO ceramic target. Typical sputtering conditions are an atmosphere=Ar, a pressure=0.5 Pa, no substrate heating, and sputtering power=1 kW. Thereby, an amorphous SRO film with a thickness of about 1 to 50 nm is formed.

An SRO film serving as the third lower electrode 15 is obtained by applying thermal treatment onto the amorphous SRO film by RTO. An atmosphere and a temperature of the RTO are, for example, the oxygen atmosphere and 550 to 650° C., respectively.

The SRO film serving as the third lower electrode 15 compensates oxygen deficiency in the PZT film occurred in the process of manufacturing the semiconductor device. Moreover, by forming an SRO film (which is not formed in the present embodiment) between the PZT film and the upper electrode thereon, it is possible to more efficiently compensate oxygen deficiency in the PZT film occurred in the process of manufacturing the semiconductor device. Oxygen deficiency in the PZT film occurred in the process of manufacturing the ferroelectric capacitor is compensated by the SRO film, with the result that fatigue characteristic, imprinting characteristic, hysteresis characteristic, and resistance to process damage are improved.

A first amorphous PZT film 16a is formed on the third lower electrode 15.

The first amorphous PZT film 16a is formed by RF magnetron sputtering process using a PZT ceramic target in which an amount of Pb is increased by about 10%. The composition of the PZT ceramic target is Pb_{1.10}La_{0.05}Zr_{0.4}Ti_{0.6}O₃.

When the density of the PZT ceramic target is high, a sputtering rate becomes higher. When the density of the PZT ceramic target is high, environment resistance to moisture or the like becomes higher. So, in the present embodiment, a PZT ceramic target made of a ceramic sintered body having a theoretical density of 98% or more is used. Typical sputtering conditions are an atmosphere=Ar, a pressure=0.5 to 2.0 Pa, sputtering power=1.0 to 1.5 kW, and a deposition time=about 1 to 2 minutes. Thereby, a first amorphous PZT film 16a with a thickness of about 100 to 150 nm is obtained.

During sputtering, evaporation of Pb from the silicon substrate or re-sputtering occurs because there are an increase in substrate temperature by plasma and bombardment by incoming particles. The evaporation of Pb and re-sputtering may cause deficiency of Pb in the first amorphous PZT film 16a. The Excess Pb contained in the ceramic target compensates the deficient Pb, and promotes crystallization of the first amorphous PZT film 16a by RTA (rapid thermal anneal). Because elements such as Zr, Ti, and La are brought into the film in substantially the same quantity as the target composition, it suffices to use a target with a desired ratio of an amount of composition.

When the electric characteristic of the PZT film is made unstable because of the composition of the PZT film obtained by crystallizing the first amorphous PZT film 16a, the deposition conditions for the first amorphous PZT film 16a are changed. For example, the process is changed to sputtering process innovating oxygen.

A thin PZT layer, or a Ti film, a Zr film, an Nb film, a Ta film or the like which is thin of about 2 to 5 nm may be used as a seed layer of the first amorphous PZT film 16a. The seed layer is formed on the third lower electrode 15 (SRO film) or the Ir electrode.

Further, before the first amorphous PZT film 16a is formed, pre-sputtering for about 10 to 30 minutes may be carried out under the same sputtering conditions as those for the first amorphous PZT film 16a, in order to stabilize a state and a temperature of the surface of the PZT ceramic target, and an environment in the chamber. An amount of Pb in the first amorphous PZT film 16a and the structure and electric characteristic of the crystallized first amorphous PZT film 16a are greatly changed by the above-described pre-sputtering. Accordingly, it is possible to form a favorable PZT film by carrying out the pre-sputtering.

[FIG. 6]

The first amorphous PZT film 16a is crystallized by RTA, and the first PZT film (PZT crystalline film) 16 having a crystalline structure is formed. In this case, a Zr/Ti ratio of the first PZT crystalline film 16 is 40/60 (x/1−x (Zr/Ti)=40/60).

The crystalline structure of the first PZT crystalline film 16 was examined by X-ray diffraction. As a result, the first PZT crystalline film 16 had a tetragonal perovskite phase, and an extremely strong reflection was obtained from the (111) plane. That is, it has been verified that the first PZT crystalline film 16 is a ferroelectric film including Pb(ZrₓTi₁₋ₓ)O₃ and having a tetragonal crystal system whose crystal direction is oriented in a <111> direction.

As the third lower electrode 15 is the thin SRO film, in some cases, the third lower electrode 15 is brought into the first PZT crystalline film 16 and crystallized at the time of crystallizing the first amorphous PZT film 16a.

When an SRO film is formed between the PZT film and the upper electrode thereon, the SRO film is formed after the PZT film is crystallized, so that a clear interface is formed between the SRO film and the PZT film.

As the third lower electrode 15 is a thin SRO film, the crystalline planes ((111) planes) of the Ir system electrodes serving as the first and second lower electrodes 12 and 13 are reflected on the first PZT crystalline film 16, and the first PZT crystalline film 16 is oriented in the <111> direction.

[FIG. 7]

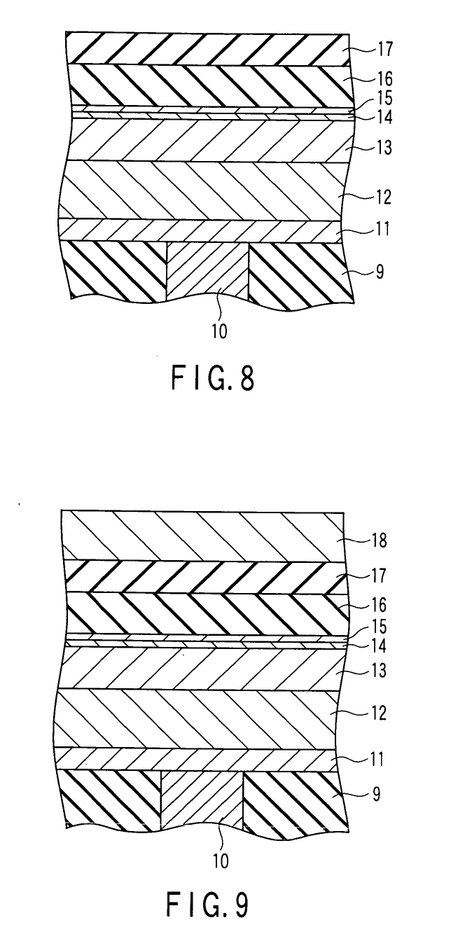

A second amorphous PZT film 17a is formed on the first crystalline film 16. The second amorphous PZT film 17a is formed by the same process as that for the first amorphous PZT film 16a except for the target composition of the PZT ceramic target. The target composition is Pb_{1.10}La_{0.05}Zr_{0.3}Ti_{0.7}O₃. Thereby, the second amorphous PZT film 17a having the composition (Zr/Ti ratio) different from that of the first amorphous PZT film 16a is formed.

[FIG. 8]

The second amorphous PZT film 17a is crystallized by RTA (rapid thermal anneal), and the second PZT film (PZT crystalline film) 17 having a crystalline structure is formed.

Here, a Zr/Ti ratio of the second PZT crystalline film 17 is 30/70 (y/1−y (Zr/Ti)=30/70).

The second PZT crystalline film 17 was examined by X-ray diffraction. As a result, it has been verified that the second PZT crystalline film 17 has a tetragonal perovskite phase, and an extremely strong reflection is obtained from the (111) plane. That is, it has been verified that the second PZT crystalline film 17 is a ferroelectric film including Pb(Zr_{y}Ti_{1-y})O₃ and having a tetragonal crystal system whose crystal direction is oriented in a <111> direction.

In this way, a multilayer PZT crystalline film including the tetragonal PZT crystalline films 16 and 17 whose compositions (Zr/Ti ratios) are different from each other is obtained. Because the crystal systems of the PZT crystalline films 16 and 17 are tetragonal, the PZT crystalline films 16 and 17 are to have great amount of polarization. Further, as the PZT crystalline films 16 and 17 are oriented in the <111> direction, the ferroelectric memory is to have a great amount of signal, and small variation of the signal due to small variation of coercive field.

This is because, in case of tetragonal PZT having the polarization axis in the <111> direction, inclinations of the polarization axes against the electric field direction are made same in all the films oriented in the <111> direction, so that a constant coercive voltage (coercive field) and a constant amount of polarization are provided independently of a direction of in-plane direction of the PZT film.

Further, formations of so-called a-domain and c-domain such as <001> and <100> oriented films are not brought about, and all domains are to contribute to amount of switching electric charges (amount of polarization) of the capacitor. In the <001> and <100> oriented films, the stress applied onto the films by the mechanism further a profound effect on amount of polarization. However, the effect thereof is smaller in a case of a <111> oriented film. This shows the fact that there is a less change in the hysteresis characteristic in accordance with a lower electrode material, a thermal treatment process, a film thickness, a stress field at a peripheral part of the capacitor, an upper electrode material, an upper electrode film thickness, and a process, which makes it possible to supply a stable capacitor.

In this embodiment, crystallization has been carried out for each of the amorphous PZT films 16a and 17a. However, the amorphous PZT films 16a and 17a may be simultaneously crystallized. That is, the amorphous PZT films 16a and 17a are sequentially formed, and thereafter, the amorphous PZT crystallization films 16a and 17a may be simultaneously crystallized by RTA.

Here, the number of the PZT crystallization films is two. However, this may be three or more. Crystallization of three or more amorphous PZT films may be carried out for each of the amorphous PZT films, or may be carried out collectively for the three or more amorphous PZT films. In addition, at least two of the three or more amorphous PZT films may have different thicknesses, or all the three or more amorphous PZT films may have the same thickness.

In the present embodiment, the y/1−y (Zr/Ti) ratio of the second PZT crystalline film 17 is greater than that of the first PZT crystalline film 16. In other words, the first PZT crystalline film 16 (a part contacting the lower electrode) has a composition whose Ti quantity is less than that of the second PZT crystalline film 17 (a part contacting the upper electrode).

In contrast, the x/1−x (Zr/Ti) ratio of the first PZT crystalline film 16 may be greater than that of the second PZT crystalline film 17. In this case as well, the same effect as that in the present embodiment can be expected by appropriately changing a film thickness ratio (the first PZT crystalline film 16/(the film thickness of the first PZT crystalline film 16+the second PZT crystalline film 17)) or the like.

[FIG. 9]

An upper electrode 18 is formed on the second PZT crystalline film 17.

Here, the upper electrode 18 is an IrO₂ film (a film made of IrO₂ as a main material). The IrO₂ film is formed by DC magnetron sputtering process.

The deposition conditions for the IrO₂ film are, for example, a sputtering power=0.5 to 1 kW, an Ar/O₂ flow ratio=about 30/70 to 10/90, and a pressure=0.5 Pa. A deposition temperature is preferably a room temperature, or not higher than 100° C. In a case of the above-described deposition conditions, a thickness of the IrO₂ film is set within 40 to 100 nm. Even in a case of chemical sputtering using an Ir target, an amount of oxygen brought into the IrO₂ film is increased if a sputtering power is reduced or an oxygen flow rate is increased.

By using an IrO₂ film (noble metal oxide electrode) as the upper electrode 18, it is possible to suppress deterioration of characteristic by process such as CVD process, RIE process, wiring process, sinter process, or packaging process after forming the capacitor. Thereby, even at a product level, an attempt can be made, for example, to increase an amount of signals, reduce leakage current, improve the fatigue characteristic, improve the retention characteristic, and improve the imprinting characteristic.

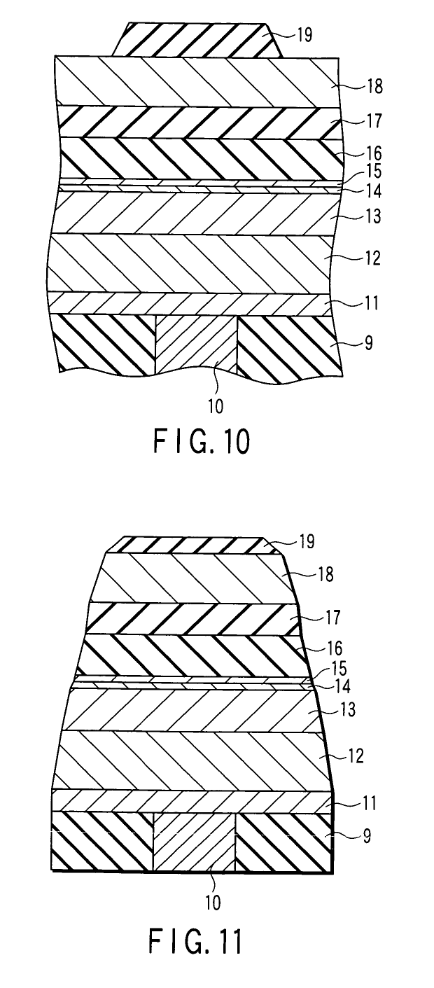

Here, a single layer noble metal oxide electrode is used as the upper electrode 18, but a multilayer noble metal oxide electrode may be used. At this time, by using the multilayer noble metal oxide electrode whose respective layers have different minute structures of a grain diameter or the like, and have different oxygen/hydrogen permeability, it is possible to further improve the above-described effect.

[FIG. 10]

A hard mask 19 comprising a silicon oxide film is formed on the upper electrode 18.

A method of forming the hard mask 19 includes a process for forming a silicon oxide film on the upper electrode 18 by CVD process, a process for forming a photoresist pattern on the silicon oxide film, a process of etching the silicon oxide film by using the photoresist pattern as a mask, and a process of removing the photoresist pattern by ashing.

In the process of etching the silicon oxide film, RIE process is used. A halogen group gas such as CHF₃ or CF₄ is used as an etching gas. The etching is performed at a room temperature.

As an example of the mask used at the time of etching the respective films constituting the ferroelectric capacitor into the predetermined shape by RIE process, a usual photoresist pattern is cited. However, a hard mask is used in many cases due to, for example, the reasons that a selected ratio of the photoresist pattern cannot be made high, and the photoresist pattern cannot afford to endure high temperature RIE process for increasing taper angles at the capacitor side faces.

The reason why the high temperature RIE process is used will be described. The noble metal films such as a Pt film and an Ir film in the ferroelectric capacitor have no chemical compound with a high vapor pressure. For this reason, during the RIE process to the noble metal films, problems occur such as reattachment of noble metal onto the capacitor side faces, and generation of fences formed of noble metal. Such problems can be solved by taper etching. At this time, it is necessary to make a taper angle greater in order not to disturb the miniaturization of the capacitor. Therefore, the high temperature RIE process is required.

[FIG. 11]

By using the hard mask 19 as a mask, the upper electrode 18 (IrO₂ film), the second PZT crystalline film 17, the first PZT crystalline film 16, the third lower electrode 15 (SRO film), the Pt thin film 14, the second lower electrode 13 (IrO₂ film), the first lower electrode 12 (Ir film), and the barrier film 11 (TiAlN film) are etched by high temperature RIE process, so that the ferroelectric capacitor having a predetermined shape is obtained.

At this time, the hard mask 19 is made thinner. However, the hard mask 19 can maintain the mask function until the etching to the first lower electrode 12 is completed.

A mixed gas containing a halogen gas (for example Cl₂), O₂, and Ar is used for the etching to the upper electrode 18 (IrO₂ film), and substrate temperature is set to high temperature, for example, 250 to 400° C.

A mixed gas containing a halogen gas (for example Cl₂), a gas based on a halogen gas (for example, CF₄), O₂, and Ar is used for the etching to the PZT crystalline films 16 and 17, and substrate temperature is set to high temperature.

A same kind of mixed gas containing a halogen gas is used for the etching to the third lower electrode 15 (SRO film), the Pt thin film 14, the second lower electrode 13 (IrO₂ film), and the first lower electrode 12 (Ir film) (for example, a mixed gas of Cl₂ and Ar for the SRO film), and substrate temperature is set to high temperature.

After the high temperature RIE process is completed, removal of the hard mask 19, water rinsing, or the like are performed to complete the process of processing the capacitor.

After the process of processing the capacitor, the ferroelectric memory is completed through the well-known process such as a back-end process, a process for forming a passivation film (for example, a CVD silicon nitride film), and a pad process.

A capacitor portion, a transistor portion, and a wiring portion are connected by the above-described back-end process. The back-end process includes a wiring process. The wiring process includes a series of processes (multilayer wiring process) such as a process for forming insulating films (for example, a CVD insulating film, an SiOx film by applying and thermal processing or the like, an interlayer insulating film such as a low-dielectric constant film or an organic film, and a silicon nitride film as a barrier film), a process for forming connection hole and trench (which includes, for example, a process of depositing insulating films such as an oxide film, and a process of etching the insulating films by RIE process), a process for forming the barrier film (which includes, for example, a process of depositing a TiN film, a Ta film, and a TaN film by sputtering or CVD process), a process for forming a conductive film serving as wiring (for example, a process for forming an Al film by sputtering process, a process for forming a Cu film by sputtering process or plating, or the like), and a process of processing the conductive film into a wiring form (for example, etching to the Al film by RIE process, planarization of the Cu film by CMP process).

The ferroelectricity of the PZT crystalline films formed by process in the present embodiment was examined by hysteresis characteristic of electric charge—applied voltage. As a result, about 40 μC/cm² was obtained in 2 Pr (an amount of residual polarization×2) at the time of applying 2.5V. Further, it has been verified that the PZT rystalline films have residual polarization and coercive voltage which are substantially equal on the entire surface of a Si wafer of 8 inches. That is, it has been verified that in-plane variations in residual polarization and a coercive voltage are little. A low value of about 0.6V was obtained as a coercive voltage. The values of residual polarization and switching electric charge are substantially equal in the capacitors having a size of 0.5 to 50 μm squares. That is, the memory performance as designed is easily achieved.

In addition, when the fatigue characteristic of the PZT capacitor in the present embodiment were evaluated by arrays corresponding to an area of 50 μm×50 μm, there was no change in polarization up to 1×10¹² cycles, and a leakage current was small close to 10⁻⁷ A/cm² order at the time of applying 2.5V. An imprinting evaluation was performed as follows. That is, the capacitor subjected to polarization switching was retained at 150° C. and for 100 hours, thereafter, hysteresis measurement was performed. As a result, a hysteresis shift corresponding to an initial amount of polarization was obtained, and an amount of polarization retained after imprinting was greater than that in a single composition capacitor. That is, the memory performance as designed was easily achieved.

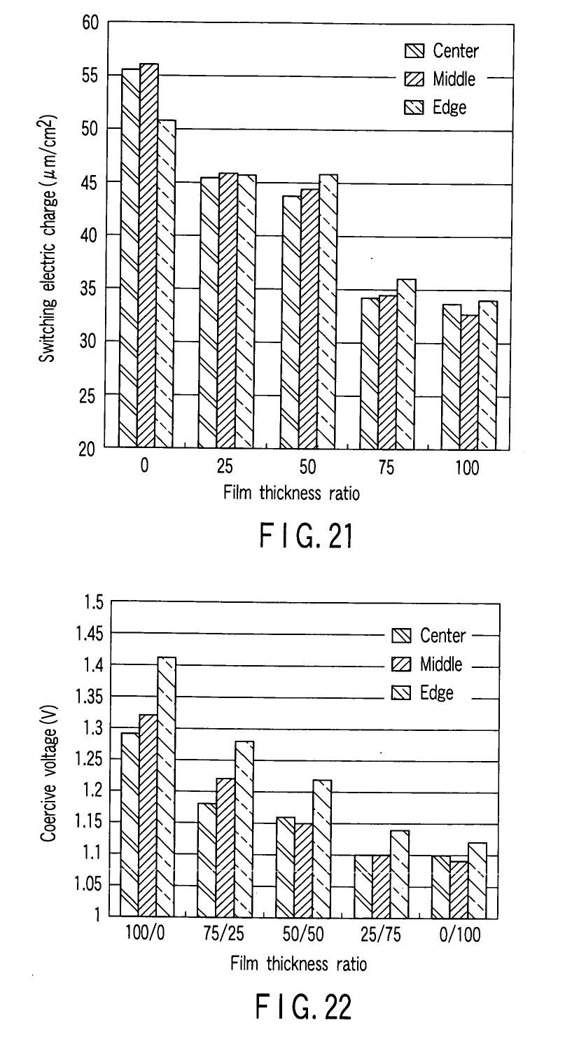

FIG. 21 is a graph showing a relationship between percentages of a film thickness d1 of the first PZT crystalline film 16 with respect to a sum of the film thickness d1 of the first PZT crystalline film 16 and a film thickness d2 of the second PZT crystalline film 17 (film thickness ratio) and switching electric charge (=2 Pr). In FIG. 21, Center denotes a central portion of the wafer, Edge denotes of a peripheral portion of the wafer, and Middle denotes a portion between the central portion of the wafer and the peripheral portion of the wafer.

It can be seen from FIG. 21 that amount of polarization is reduced in proportion to the film thickness ratio independently of a location of the wafer, and a quantity of switching electric charges can be controlled by the film thickness ratio between the first PZT crystalline film 16 and the second PZT crystalline film 17. Even if a Zr/Ti ratio between the first and second PZT crystalline films 16 and 17 was changed, the same result was obtained as long as the first PZT crystalline film 16 was Zr-rich as compared with the second PZT crystalline film 17.

That is, it has been verified a ferroelectric capacitor having a quantity of switching electric charges as designed can be easily realized by controlling film thickness ratio of the tetragonal system first and second PZT crystalline films 16 and 17.

FIG. 22 is a graph showing a relationship between ratio (film thickness ratio) of a thickness of a first PZT crystalline film to a sum (total film thickness) of the film thickness of the first PZT crystalline film and a film thickness of a second PZT crystalline film and amount of switching electric charge. Here the total film thickness) is set as 100.

In FIG. 22, the coercive voltage is a sum (Vc+|−Vc|) of a coercive voltage at the positive side (Vc) and an absolute value of a coercive voltage at the negative side (−Vc). Further, in FIG. 22, Center denotes a central portion of the wafer, Edge denotes of a peripheral portion of the wafer, and Middle denotes a portion between the central portion of the wafer and the peripheral portion of the wafer.

It can be seen from FIG. 22 that the amount of polarization is reduced in proportion to the film thickness ratio independently of location of the wafer, and the coercive voltage can be controlled by the film thickness ratio between the first PZT crystalline film 16 and the second PZT crystalline film 17. Even if a Zr/Ti ratio between the first and second PZT crystalline films 16 and 17 was changed, the same result is obtained as long as the first PZT crystalline film 16 was Ti-rich and the second PZT crystalline film 17 was Zr-rich.

That is, it has been verified that the ferroelectric capacitor having the coercive voltage as designed can be easily realized by controlling the film thickness ratio of the tetragonal system first and second PZT crystalline films 16 and 17.

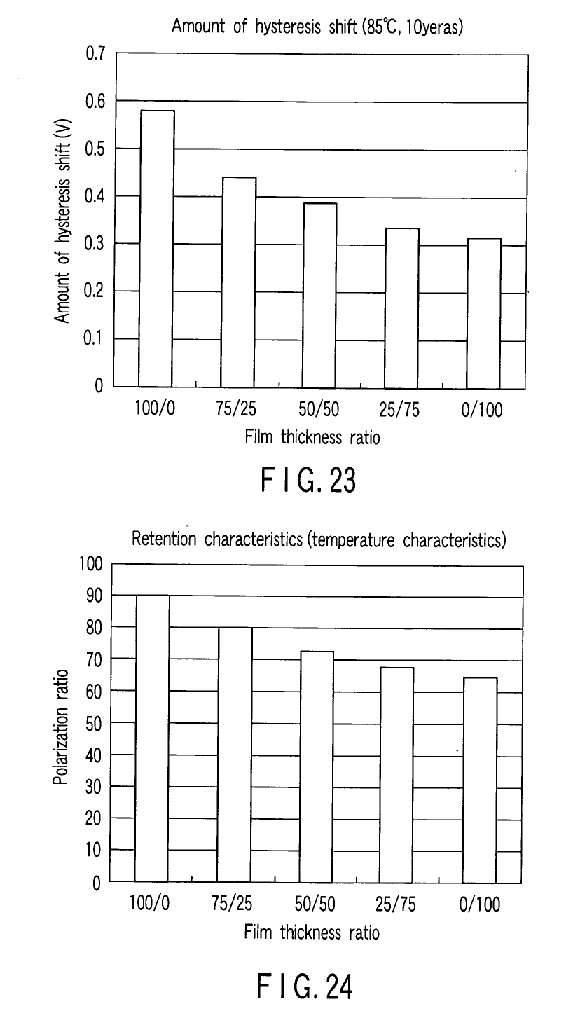

FIG. 23 is a graph showing a relationship between a ratio (film thickness ratio) of a thickness of a first PZT crystalline film to a sum (total film thickness) of the film thickness of the first PZT crystalline film and a film thickness of a second PZT crystalline film and amount of hysteresis shift. Here the total film thickness is set as 100.

It can be seen from FIG. 23 that the amount of hysteresis shift is reduced in proportion to the film thickness ratio, and the amount of hysteresis shift can be controlled by the film thickness ratio between the first PZT crystalline film 16 and the second PZT crystalline film 17. Even if a Zr/Ti ratio between the first and second PZT crystalline films 16 and 17 was changed, the same result was obtained as long as the first PZT crystalline film 16 was Ti-rich and the second PZT crystalline film 17 was Zr-rich.

That is, it has been verified that the ferroelectric capacitor having the amount of hysteresis shift as designed can be easily realized by controlling the film thickness ratio of the tetragonal system first and second PZT crystalline films 16 and 17.

FIG. 24 is a graph showing a relationship between a ratio (film thickness ratio) of a thickness of a first PZT crystalline film to a sum (total film thickness) of the film thickness of the first PZT crystalline film and a film thickness of a second PZT crystalline film and a ratio of amount of polarization (amount of polarization at 85° C./amount of polarization at RT). Here, the total film thickness is set as 100.

It can be seen from FIG. 24 that the amount of polarization is reduced in proportion to the film thickness ratio, and a ratio of amount of polarization, i.e., retention characteristic (temperature characteristic) can be controlled by the film thickness ratio between the first PZT crystalline film 16 and the second crystalline film 17. Even if a Zr/Ti ratio between the first and second PZT crystalline films 16 and 17 was changed, the same result was obtained as long as the first PZT crystalline film 16 was Ti-rich and the second PZT crystalline film 17 was Zr-rich.

That is, it has been verified that the ferroelectric capacitor having the retention characteristic (temperature characteristic) as designed can be easily realized by controlling a film thickness ratio between the tetragonal system first and second PZT crystalline films 16 and 17.

As the PZT films are crystallized on the lower electrodes, the characteristic of the PZT films are greatly affected by the material and structure of the lower electrodes. However, the effect is reduced in the present embodiment.

Modified examples of the present embodiment are shown in FIGS. 25A and 25B.

FIG. 25A shows an example in which the first PZT crystalline film comprises three PZT crystalline films 16. In the same manner, the second PZT crystalline film 17 may comprise a plurality of PZT crystalline films. Moreover, the first and second PZT crystalline films may comprise respectively a plurality of PZT crystalline films. Furthermore, those may comprise respectively three or more PZT crystalline films whose Zr/Ti ratios are different from one another. The film thicknesses may be the same or different from each other.

FIG. 25B shows an example in which a PZT crystalline film 16′ doped with dopant is provided on the undoped PZT crystalline film 16. A crystalline structure and a Zr/Ti ratio of the PZT crystalline film 16′ are the same as those of the PZT crystalline film 16. Examples of dopant doped into site A in an ABO₃ perovskite crystalline structure is Sr, Ca, La, Ba, or the like. Examples of dopant doped into site B is Nb, Mn, Co, Ni, Fe, or the like.

Here, the PZT crystalline film 16′ is provided on the PZT crystalline film 16. To the contrary, the PZT crystalline film 16 may be provided on the PZT crystalline film 16′. Moreover, both the two PZT crystalline films may be PZT crystalline films doped with dopant. The film thicknesses may be the same, or different from each other. Furthermore, the PZT crystalline film 16′ may be provided on and under the PZT crystalline film 16. In this case as well, all the three PZT crystalline films may be PZT crystalline films doped with dopant. The film thicknesses may be the same, or different from each other.

Dopant has the effect of compensating oxygen deficiency under the electric charge neutrality condition at the time of doping elements having different valences into the sites A and B in the perovskite structure. Generally, oxygen deficiency in the perovskite structure is easily occurred, and this has an enormous effect on the fatigue characteristic, the retention characteristic, and additionally the imprinting characteristic, from the standpoint of an application as the ferroelectric memory. Further, the leakage characteristic also affects on the electric characteristic in such a manner that a carrier is generated by bringing about deficiency such as oxygen vacancy, or a carrier is grasped with oxygen vacancy or positive ion being as a trap. In addition, Curie point, amount of polarization, coercive field, a dielectric constant, a crystalline structure, or the like are changed by carrying out doping into the PZT ferroelectric.

On the other hand, reduction resistance process characteristic of the capacitor ferroelectric film is improved by applying doping. The perovskite PZT has bonding of Pb and oxygen. However, bond energy thereof is lower than that of Sr, Ba, or the like which are other alkaline earth metals. The reduction resistance is expected to be improved by doping these elements having higher bond energy. It can be estimated that a ferroelectric capacitor structure is formed so as to have many defects on the upper electrode interface and the lower electrode interface in particular, and it is possible to improve the process resistance by using PZT in which doping has been applied to the portions, and it is possible to ensure a sufficient amount of polarization even after a multilayer wiring layer is formed.

In these modified examples, the crystallization process for forming a plurality of PZT crystalline films may be carried out for each layer, or may be carried out collectively.

### SECOND EMBODIMENT

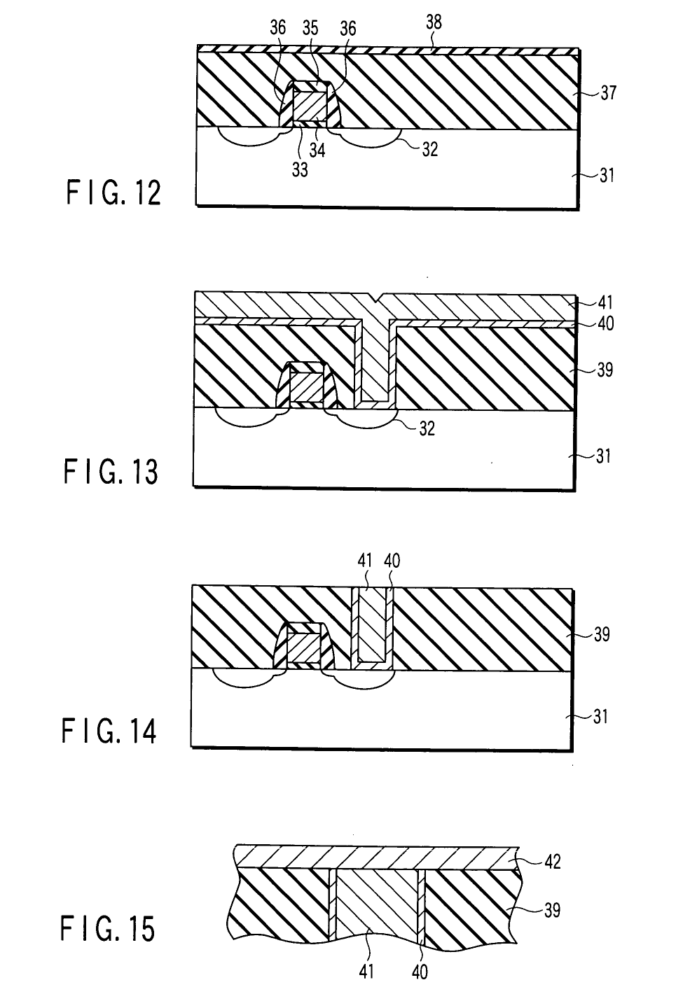

FIGS. 12 to 20 are cross-sectional views showing process for manufacturing a ferroelectric memory according to a second embodiment of the present invention.

[FIG. 12]

First, MOS transistors are formed on a silicon substrate 31 by well-known process, and then a CMOS structure is formed. For ease of explanation, only one MOS transistor is shown in FIG. 12.

In FIG. 12, reference numeral 32 denotes source/drain regions, 33 denotes a gate insulating film, 34 denotes a gate electrode, 35 denotes a gate upper insulating film (for example, a silicon nitride film), and 36 denotes a spacer (for example, a silicon nitride film).

A SiO₂ insulating film 37 such as a PSG film or a BPSG film is deposited on a region (transistor region) including the CMOS structure by CVD process, and then, the surface of the SiO₂ insulating film 37 is planarized by CMP process. A laminated insulating film 38 including a silicon oxide film and a silicon nitride film is deposited on the SiO₂ insulating film 37 by CVD process. The order of laminating the silicon oxide film and the silicon nitride film is arbitrary. Hereinafter, the SiO₂ system insulating film 37 and the laminated insulating film 38 are collectively referred as an interlayer insulating film 9.

[FIG. 13]

A connection hole reaching the source/drain regions 32 is formed in the interlayer insulating film 39 by etching the interlayer insulating film 39, thereafter, a barrier metal film 40 (for example, Ti/TiN film) is formed on a region including the transistor region so as to cover the inner surfaces (the bottom surface and the side surface) of the connection hole, further, a conductive film (here, a W film) 41 to be a plug is deposited on the barrier metal film 40 by CVD process.

[FIG. 14]

By means of CMP process, a plug 31 is formed by removing the W film 41 and the barrier metal film 40 outside the connection hole, and the surface of the region including the transistor region is planarized.

[FIG. 15]

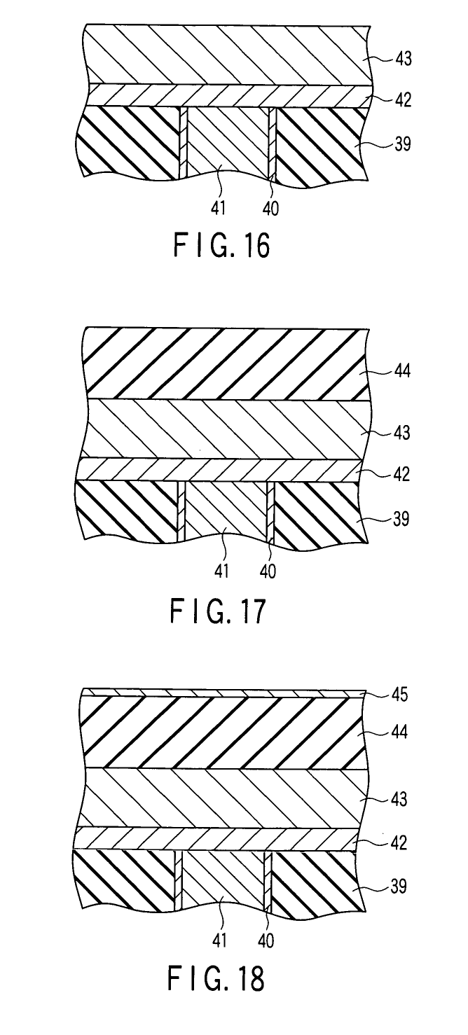

An adhesion layer 42 is formed on a region including the plug 41. The adhesion layer 42 enhances the adhesiveness between the plug 41 and the lower electrode. The adhesion layer 42 is, for example, a Ti film with a thickness of 10 nm. The Ti film is formed by sputtering process.

[FIG. 16]

A lower electrode 43 is formed on the adhesion layer 42. Here, the lower electrode 43 is an Ir film. The Ir film is formed by sputtering process. A thickness of the Ir film is favorably about 100 to 150 nm.

An Ir film has high barrier characteristic. Therefore, the Ir film serving as the lower electrode 43 has an effect of suppressing contact failure which may be occurred when the top surface of the plug 41 is oxidized during a process for forming a PZT film, a process for forming an SRO film (a first upper electrode) (a heat process at 500 to 650° C. in the atmosphere including oxygen (crystallization process), or anneal process for restoring the capacitor from process damages (anneal process at 450 to 650° C. in the atmosphere including oxygen). In order to improve the crystalline characteristic of the Ir film, temperature during forming the Ir film (at the time of sputtering process) is preferably a temperature of 200 to 400° C.

As the lower electrode 43, other than the Ir film, a Pt film, an Ru film, an RuO₂ film, an IrO₂ film, or a laminated film including at least two thereof, or a film made of a mixture including at least two among It, Pt, Ru, RuO₂, and IrO₂ may be used. A thickness of the lower electrode 42 is not limited in particular unless the plug 41 is not oxidized in the process of manufacturing the capacitor.

[FIG. 17]

A PZT crystalline film 44 is formed on the lower electrode 43 by MOCVD process. The crystallization of PZT is occurred in In-situ (during deposition). As the foundation of the PZT crystalline film 44 is the Ir film (the lower electrode 43), the PZT crystalline film 44 is oriented in the <111> direction.

The MOCVD process has advantages that step coverage is favorable with respect to an electrode structure, the composition controllability is excellent, a uniform high quality film is obtained on an large area, a deposition rate is high, feasibility of thinning a ferroelectric film (feasibility of low voltage operation), or the like. Representative examples of source material of PZT used in the MOCVD process is Pb(dpm)₂ as a Pb source, Zr(dpm)₄ or Zr(O-tC4H9)₄ as a Zr source, and Ti(O-iC₃H₇)₄ or Ti(O-iC₃H₇)₂(dpm)₂ as a Ti source.

The above-described PZT source materials are used to be mixed with THF (tetrahydrofuran). In a case of a solution vapor method, there are many types of carburetors for carrying out vaporization of the source materials, and there are one atomizing a solution by ultrasonic wave, one spraying a solution onto a hot plate, one utilizing an atomizer, or the like. Depending on the source material, substrate temperature is preferably in the vicinity of 600° C. N₂O or O₂ is simultaneously supplied as an oxidant. A Zr/Ti ratio is changed in the process of depositing PZT to form the PZT crystalline film 44 whose composition changes in the thickness direction.

First, a PZT film (Zr/Ti=20/80) serving as the first layer is formed. As the composition is Ti-rich, the Zr/Ti ratio is adjusted by increasing flow rate of the Ti source during the deposition. After the PZT film of 50 nm is formed under the conditions, the flow rate of Zr/Ti is changed to form a PZT film serving as the second layer. Next, the flow rate of Ti is decreased, and the flow rate of the Zr source gas is increased. In this process, the flow rates of the Zr and Ti sources may be changed continuously in the process of depositing the PZT films, or a PZT film having different composition may be formed after deposition of one composition is once executed. In addition, in the case of MOCVD process, it is possible to slope the composition at the interfaces with different compositions of the PZT films by continuously changing the flow rates of the sources. The PZT crystalline film 44 includes a plurality of PZT films having different Zr/Ti ratios, however, for ease of explanation, the PZT crystalline film 44 is shown by one film in the drawing.

[FIG. 18]

A first upper electrode 45 is formed on the PZT crystalline film 44. Here, an SRO film is formed as the first upper electrode 45.

The process for forming the SRO film includes a process for forming an amorphous SRO film by sputtering process, and a process of crystallizing the amorphous SRO film by RTO (a heat process at 500 to 650° C. in the atmosphere including oxygen). A thickness of the PZT crystalline film 44 is preferably about 50 to 150 nm. The process for forming the amorphous SRO film is carried out under the same deposition conditions as those in the case of the lower electrode 15 in the first embodiment.

In the method for forming the SRO film, an Ex-situ crystallization method is employed in which an amorphous SRO film is formed, thereafter, the amorphous SRO film is crystallized by anneal in the oxygen atmosphere such as RTO. In place of the Ex-situ crystallization method, an In-situ crystallization method may be used in which an SRO film is formed at high temperature, and crystallization is performed during the process for forming the SRO film.

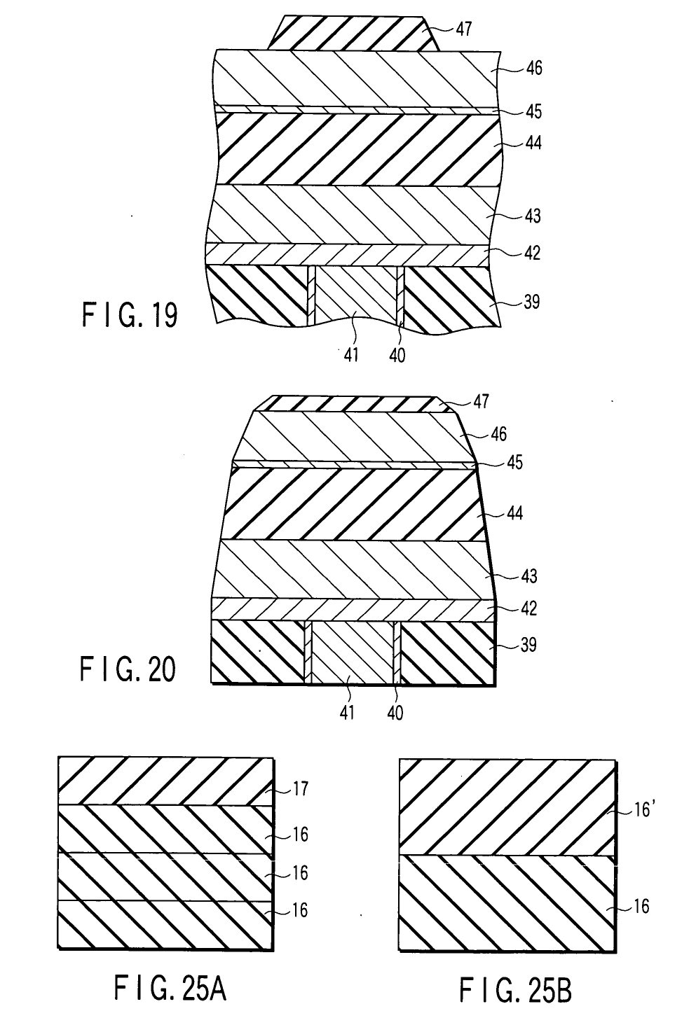

The first upper electrode 45 comprising the SRO film (oxide film having conductivity) is inserted between the PZT crystalline film 44 and a second upper electrode (IrO₂ film) 46 to be formed at the following process (FIG. 19), thereby the capacitor characteristic is improved.

The same effect can be obtained using the following oxide film having the conductivity in place of the SRO film.

Those are an SRTO (Sr(Ru, Ti)O₃: TiO—50 mol %) film, a CaRuO₃ film, an (Sr, X)RuO₃ film, a SrIrO₃ film, a BaPbO₃ film, a BaPb₁₋ₓBixO₃ film, an LSCO ((La, Sr)CoO₃) film, and an LNO (LaNiO₃) film, a film made of an oxide superconductive material, and a film made of a semiconductor perovskite oxide.

Examples of process for forming the oxide film having conductivity (the first upper electrode 45) is sputtering process such as DC magnetron sputtering process, RF magnetron sputtering process, helicon sputtering process, and ion beam sputtering process. Other examples of the process is PVD process such as laser ablation process and EB evaporation process, and CSD process such as sol-gel process and MOD process, and CVD process such as MOCVD process.

[FIG. 19]

A second upper electrode 46 is formed on the upper electrode 45. Here, the upper electrode 46 is an IrO₂ film. It is important to form the IrO₂ film under conditions that oxygen content in the IrO₂ film is to large. In a case of chemical sputtering process using an Ir target, amount of oxygen brought into the IrO₂ film during deposition is increased by lowering sputtering power or increasing oxygen flow rate.

A hard mask 47 comprising a silicon oxide film is formed on the second upper electrode 46. A method of forming the hard mask 47 is the same as that for the hard mask 19 in the first embodiment.

As the upper electrode 45, aside from the IrO₂ film, a film made of a noble metal oxide (for example, an RuO₂ film, an RhO₂ film), a film made of a mixture of two or more kinds of noble metals (for example, a mixture of Pt and Ir), a film made of a mixture of two or more kinds of noble metals (for example, a mixture of RuO₂ and IrOx), a film made of a mixture of a noble metal and a noble metal oxide, or a film made of one of the above-described main materials is used, and the same effect can be expected.

[FIG. 20]

By using the hard mask 47 as a mask, the second upper electrode 46 (IrO₂ film), the first upper electrode 46 (SRO film), the PZT crystalline film 44, and the lower electrode 43 (Ir film) are etched by high temperature RIE process, so that a ferroelectric capacitor having a predetermined form is obtained.

At this time, the hard mask 47 is made thinner, however, the hard mask 47 can maintain the mask function until the etching to the lower electrode 43 is completed.

Here, a mixed gas including a halogen gas (for example Cl₂), O₂, and Ar is used for the etching to the second upper electrode 46 (IrO₂ film), and substrate temperature is set at high temperature, for example, 250 to 400° C.

A mixed gas including a halogen gas (for example Cl₂), a gas (for example, CF₄) based on a halogen gas, O₂, and Ar is used for the etching to the PZT film 44, and substrate temperature is set at high temperature.

A same kind of mixed gas including a halogen gas is used for the etching to the first upper electrode 45 (SRO film) and the lower electrode 43 (Ir film) (for example, a mixed gas of Cl₂ and Ar for the SRO film), and substrate temperature is set at high temperature.

After the etching to the lower electrode 43 is completed, removal of the hard mask 47, water rinsing, or the like are carried out to complete the process of processing the capacitor.

After the process of processing the capacitor, the ferroelectric memory is completed through the well-known processes such as a back end process, a process for forming a passivation film, a pad process, or the like, in the same manner as in the first embodiment.

The ferroelectricity of the PZT crystalline films formed by process of the present embodiment was examined by hysteresis characteristic of electric charge—applied voltage. As a result, about 40 μC/cm² was obtained in 2 Pr (an amount of residual polarization×2) at the time of applying 2.5V. Further, it has been verified that the PZT crystalline films have residual polarization and coercive voltage which are substantially equal on the entire surface of a Si wafer of 8 inches. That is, it has been verified that in-plane variations in residual polarization and a coercive voltage are little. A low value of about 0.6V was obtained as a coercive voltage. The values of residual polarization and switching electric charge are substantially equal in the capacitors having a size of 0.5 to 50 μm squares. That is, the memory performance as designed is easily achieved.

In addition, when the fatigue characteristic of the PZT capacitor in the present embodiment were evaluated by arrays corresponding to an area of 50 μm×50 μm, there was no change in polarization up to 1×10¹² cycles, and a leakage current was small close to 10⁻⁷ A/cm² order at the time of applying 2.5V. An imprinting evaluation was performed as follows. That is, the capacitor subjected to polarization switching was retained at 150° C. and for 100 hours, thereafter, hysteresis measurement was performed. As a result, a hysteresis shift corresponding to an initial amount of polarization was obtained, and an amount of polarization retained after imprinting was greater than that in a single composition capacitor. That is, the memory performance as designed was easily achieved.

Note that, in the first and second embodiments, a concrete memory cell structure has not been mentioned. However, 1T/1C, 2T/2C, or the like can be quoted. Further, examples of a structure relating to a relationship between capacitor and transistor include a capacitor on plug (COP) structure. The COP structure is suitable for miniaturization and a high capacity design. Further, the semiconductor device including the ferroelectric memory of the embodiments is, for example, a general purpose nonvolatile memory card or an IC card.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate; and
a ferroelectric capacitor provided on the semiconductor substrate, the ferroelectric capacitor comprising a lower electrode; a first ferroelectric film provided on the lower electrode including Pb(ZrₓTi₁₋ₓ)O₃ and having a tetragonal crystal system whose crystal direction is oriented in a <111> direction; a second ferroelectric film provided on the first ferroelectric film including Pb(Zr_{y}Ti_{1-y})O₃ and having a tetragonal crystal system whose crystal direction is oriented in the <111> direction; and an upper electrode provided on the second ferroelectric film.

2. The semiconductor device according to claim 1,
wherein a x/1−x ratio of the first ferroelectric film and a y/1−y ratio of the second ferroelectric film are different from each other.

3. The semiconductor device according to claim 1,
wherein at least the first ferroelectric film among the firs and second ferroelectric film includes dopant.

4. The semiconductor device according to claim 2,
wherein at least the first ferroelectric film among the firs and second ferroelectric film includes dopant.

5. The semiconductor device according to claim 1,
wherein the lower electrode comprises a lower electrode contacting the first ferroelectric film and including SrRuO₃.

6. The semiconductor device according to claim 2,
wherein the lower electrode comprises a lower electrode contacting the first ferroelectric film and including SrRuO₃.

7. The semiconductor device according to claim 3,
wherein the lower electrode comprises a lower electrode contacting the first ferroelectric film and including SrRuO₃.

8. The semiconductor device according to claim 4,
wherein the lower electrode comprises a lower electrode contacting the first ferroelectric film and including SrRuO₃.

9. A method for manufacturing a semiconductor device comprising a semiconductor substrate and a ferroelectric capacitor provided on the semiconductor substrate, the method comprising:
forming the ferroelectric capacitor;
forming a multilayered lower electrode, the multilayered lower electrode including a first conductive film having a (111) plane; and a second conductive film provided on the first conductive film including SrRuO₃ and being thinner than the first conductive film;
forming a ferroelectric film on the lower electrode, the ferroelectric film including a first ferroelectric film including Pb(ZrₓTi₁₋ₓ)O₃ and having a tetragonal crystal system whose crystal direction is oriented in a <111> direction; and a second ferroelectric film provided on the first ferroelectric film including Pb(Zr_{y}Ti_{1-y})O₃ and having a tetragonal crystal system whose crystal direction is oriented in the <111> direction; and
forming an upper electrode on the ferroelectric film.

10. The method for manufacturing the semiconductor device, according to claim 9,
wherein a x/1−x ratio of the first ferroelectric film and a y/1−y ratio of the second ferroelectric film are different from each other.

11. The method for manufacturing the semiconductor device, according to claim 9,
wherein at least the first ferroelectric film among the firs and second ferroelectric film includes dopant.

12. The method for manufacturing the semiconductor device, according to claim 10,
wherein at least the first ferroelectric film among the firs and second ferroelectric film includes dopant.
